(19) United States
(12) Patent Application Publication
(10) Pub. No.: US 2009/0046421 A1
(43) Pub. Date: Feb. 19, 2009

(54) System and Method for Reducing Information Handling System Cooling Fan Noise

(76) Inventor: Richard Sohaney, Cedar Park, TX (US)

Correspondence Address: HAMILTON & TERRILE, LLP, P.O. BOX 203518, AUSTIN, TX, 78720, US

(21) Appl. No.: 11/839,315

(22) Filed: Aug. 15, 2007

(51) Int. Cl. H05K 7/20; H02K 1/27; H02K 15/03

(52) U.S. Cl. 361/687; 29/598; 310/156.47; 361/695

(57) ABSTRACT

A brushless DC electric fan cools an information handling system with reduced audible noise by skewing a seam in a permanent magnet relative to a rotation axis of the fan. For instance, the permanent magnet is formed from a sheet of magnetic material having a parallelogram shape. The parallelogram is rolled into a cylindrical shape having a seam skewed relative to the axis of rotation of the cylinder. The discontinuity in the magnetic field is moderated by passing the seam through the magnetic field over several degrees of rotation, such as approximately ten degrees.

### BACKGROUND OF THE INVENTION

1. Field of the Invention

The present invention relates in general to the field of information handling system cooling, and more particularly to a system and method for information handling system cooling fan operation with reduced audible noise.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems typically give off heat as a byproduct of powering electrical components. Generally, as information handling system components have grown more powerful, the amount of heat given off has increased. In order to remove excess heat, information handling systems generally include cooling subsystems, such as a cooling fan that circulates a cooling airflow through the information handling system chassis. The more powerful components included in information handling systems have led to the use of more and more powerful cooling fans in order to ensure that an adequate cooling airflow is available. The use of more powerful cooling fans generally results in two difficulties for information handling system design: greater power consumption and increased acoustic noise. Generally, to address these difficulties, cooling fan operations are regulated based on internal chassis temperature so that a cooling fan operates at a minimal speed that will keep the internal temperature below a designed maximum level. Nonetheless, cooling fans must still have the capability of providing a minimal level of cooling airflow so that the increasing level of heat provided as a byproduct of information handling system operation has generally required increased capability from cooling fans included in information handling systems.

Generally, brushless DC electric motors are used to turn information handling system cooling fans. Brushless DC electric motors operate in a manner similar to DC electric motors that have brushes except that a microcontroller in a brushless DC electric motor performs the application of current to coils instead of the interaction between the brushes and the coils. Brushless DC electric motors also tend to be more reliable, efficient and quiet that motors that use brushes. A brushless DC electric motor has a permanent magnet formed in a cylindrical shape around a coil and microcontroller assembly. As current is applied to the coils, the magnetic force generated by the coils interacts with the permanent magnet to cause the permanent magnet to turn. A common method for manufacture of the permanent magnet is curl a flat strip of material into a cylinder shape having an axial seam or split where the two ends of the original flat strip meet. For a typical 4-pole motor with two positive poles and 2 negative poles, the magnetic field of the permanent magnet is a sine-like wave. The seam in the permanent magnet where the folded over material meets introduces a discontinuity or disturbance in the magnetic field which, during operation of the motor, can cause an audible tone at the pole-passing frequency and harmonics. Similar audible tones are reduced in motors having a rotor constructed of stacked laminations by skewing the rotor slots, which reduces the cogging torque. However, in order to remove the discontinuity introduced by the seam of a cylindrical magnet, the magnet is typically formed from cylindrical stock instead of sheet stock. This tends to increase the cost of the magnet and, thus, the motor.

### SUMMARY OF THE INVENTION

Therefore a need has arisen for a system and method which reduces the effect of a DC brushless motor permanent magnet discontinuity on operation of the motor.

In accordance with the present invention, a system and method are provided which substantially reduce the disadvantages and problems associated with previous methods and systems for providing cooling airflow to an information handling system. A seam formed in a permanent magnet of a brushless DC electric motor is skewed relative to the rotational axis of the permanent magnet to moderate discontinuity introduced by the seam to the magnetic field of a coil.

More specifically, an information handling system has plural processing components to process information and a cooling fan to remove excess heat from the processing components. The cooling fan has a brushless DC electric motor with a cylinder-shaped permanent magnet rotating about coils on a rotational axis. A controller applies current to the coils to create a magnetic field within the cylinder shape that interacts with the permanent magnet to rotate the permanent magnet about the rotational axis. The permanent magnet is formed from a sheet of magnetic material having a parallelogram shape. The parallelogram is curled into the cylinder shape so that opposing sides of the parallelogram meet at a seam. The seam is skewed at the angle of the parallelogram relative to the rotational axis so that discontinuity introduced to the magnetic field of the permanent magnet by the seam is distributed across the magnetic field of the coil as the permanent magnet rotates.

The present invention provides a number of important technical advantages. One example of an important technical advantage is that a brushless DC electric motor operates more quietly by moderating the effect of a discontinuity throughout the rotation of a permanent magnet. Forming the permanent magnet from a sheet of magnetic material so that the seam is skewed or not parallel relative to the rotational axis of the coil offers a moderated effect from the discontinuity of the seam which extends through a predetermined amount of rotation of the magnet without a substantial increase in the cost of the magnet.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts an information handling system having cooling airflow provided by a cooling fan;

FIG. 2 depicts a blow-up view of a brushless DC electric fan having a permanent magnet seam skewed relative to the rotational axis of the permanent magnet; and

FIGS. 3A and 3B depict the forming of a cylinder-shaped permanent magnet having a seam skewed relative to the axis of rotation of the magnet.

### DETAILED DESCRIPTION

Information handling system brushless DC electric cooling fan operation has reduced acoustics by skewing a permanent magnet seam from the rotation axis of the permanent magnet. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

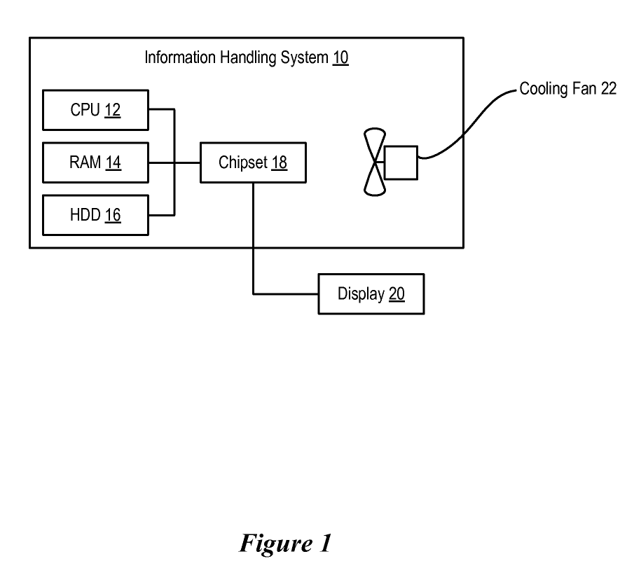

Referring now to FIG. 1, an information handling system 10 is depicted having cooling airflow provided by a cooling fan. Information handling system 10 processes information with a plurality of processing components disposed in a chassis, such as a CPU 12, RAM 14, a hard disk drive 16 and a chipset 18. For example, information processed by the processing components is presented at a display 20 external to the information handling system chassis. During operation, the processing components generate heat as a byproduct that can create temperatures is excess of the operating parameters of the processing components. In order to remove the excess heat, a cooling fan 22 is run within information handling system 10 to generate a cooling airflow over the processing components. Cooling fan 22 has a brushless DC electric motor that turns a permanent magnet relative to electric coils based on current supplied to the coils by a controller. Brushless DC electric motors are often selected to turn a variety of information handling system components, such as hard disk drives and optical drives, due to their acoustic, reliability and efficiency characteristics.

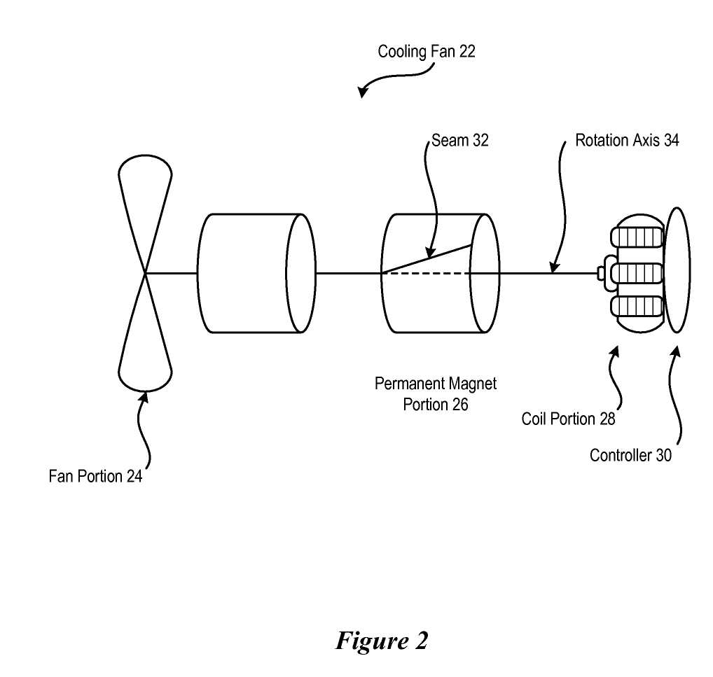

Referring now to FIG. 2, a blow-up view of a brushless DC electric cooling fan 22 is depicted having a permanent magnet seam skewed relative to the rotational axis of the permanent magnet. Cooling fan 22 has a fan portion 24 that turns in the air to generate a cooling airflow. Fan portion 24 couples over a permanent magnet portion 26 so that fan portion 24 turns as permanent magnet portion 26 is motivated to turn by the application of electric current to coil portions 28 disposed within permanent magnet portion 26. A controller 30 applies current to coil portion 28 to create a magnetic field that interacts with permanent magnet 26 so that permanent magnet 26 rotates about a rotational axis 34. Permanent magnet portion 26 has a cylinder shape to create a continuous magnetic field around coil portion 28, however, a seam 32 formed in permanent magnet 26 introduces a discontinuity to the permanent magnet portion magnetic field. The discontinuity introduced by seam 32 causes audible tones as the magnetic field of permanent magnet 26 interacts with the magnetic field of coil portion 28.

In order to reduce the effect of the discontinuity introduced by seam 32 on the operation of cooling fan 22, seam 32 is skewed relative to rotation axis 34 so that the effect of the discontinuity is distributed through a portion of the rotation of permanent magnet portion 26. In the example embodiment of FIG. 2, seam 32 is formed in cylindrical-shaped permanent magnet portion 26 with approximately ten degrees of skewing from rotation axis 34. In alternative embodiments, the amount of skewing of seam 32 may be varied to find an angle that provides a desired acoustic output, such as based upon the harmonics produced at desired rotation rates. For example, in one embodiment, the seam is between 5 and 30 degrees skewed from parallel to the rotational axis. Although FIG. 2 depicts a cooling fan portion 24 rotated by permanent magnet portion 26, in alternative embodiments, a skewed seam 32 may be incorporated into brushless DC electric motors that perform other tasks, such as rotation of a hard disk drive or optical drive. Further, although FIG. 2 depicts a single seam 32 in a cylindrical-shaped permanent magnet portion 26, in alternative embodiments, plural magnetic portions may be formed together in alternative shapes with one or more of the portions having skewed seams with varying degrees off of parallel to the axis of rotation. For example, permanent magnet portion 26 may be formed into a cylinder shape with multiple curled sheet portions, each curled sheet portion meeting with a skewed seam 32 relative to rotation axis 34.

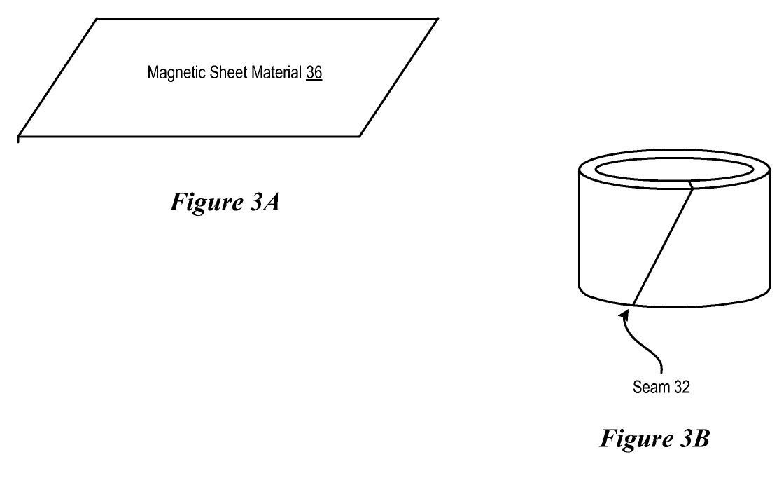

Referring now to FIGS. 3A and 3B, the forming of a cylinder-shaped permanent magnet is depicted having a seam 32 skewed relative to the axis of rotation of the magnet. A magnetic sheet material 36 is formed in a parallelogram shape having opposing parallel sides which meet at other than right angles. Magnetic sheet material 36 is curled into a cylinder shape so that one set of the parallel opposing sides meet at seam 32. Seam 32 is skewed off parallel from the center axis that runs through the cylinder shape as depicted by FIG. 3B. In alternative embodiments, plural magnetic sheet materials 36 are used with each sheet curled to form portion of the cylinder shape. Each of the plural sheets are formed as parallelograms so that each seam is skewed relative to the central axis of the cylinder.

Although the present invention has been described in detail, it should be understood that various changes, substitutions and alterations can be made hereto without departing from the spirit and scope of the invention as defined by the appended claims.

What is claimed is:

1. An information handling system comprising:
a chassis;
plural processing components disposed in the chassis, the processing components operable to process information; and
a cooling fan disposed in the chassis, the cooling fan operable to provide a cooling airflow through the chassis, the cooling fan having a permanent magnet rotating about a rotation axis, the permanent magnet having a seam skewed relative to the rotation axis.

2. The information handling system of claim 1 wherein the permanent magnet comprises a sheet of material having first and second ends rolled into a cylinder shape, the first and second ends meeting to form the seam.

3. The information handling system of claim 2 wherein the sheet of material comprises a parallelogram.

4. The information handling system of claim 2 wherein the seam comprises approximately five to thirty degrees of the cylinder shape.

5. The information handling system of claim 4 wherein the seam comprises approximately ten degrees of the cylinder shape.

6. The information handling system of claim 1 wherein the cooling fan comprises a brushless DC electric motor.

7. A method for rotating a brushless DC electric motor, the method comprising:
aligning a cylindrical-shaped magnet with a rotation axis, the cylindrical-shaped magnet having a discontinuity;
skewing the discontinuity from the rotation axis;
disposing electric coils along the rotation axis; and
applying current to the electric coils to generate a magnetic field, the magnetic field interacting with the cylindrical-shaped magnet to rotate the cylinder-shaped magnet.

8. The method of claim 7 wherein the discontinuity comprises a seam formed in the cylindrical-shaped magnet.

9. The method of claim 8 wherein skewing the discontinuity further comprises forming the cylindrical-shaped magnet from sheet material, the sheet material having first and second ends, the ends meeting at the seam.

10. The method of claim 9 wherein the sheet material comprises a parallelogram.

11. The method of claim 7 further comprising:
coupling a fan to the cylindrical-shaped magnet; and
disposing the fan in an information handling system chassis to provide a cooling airflow.

12. The method of claim 7 wherein skewing the discontinuity relative to the rotation axis further comprises:
forming the cylindrical-shaped magnet from a sheet of magnetic material, the sheet having first and second ends; and
skewing a seam formed by the first and second ends to align a predetermined angle off of the rotation axis.

13. The method of claim 12 wherein the predetermined angle comprises approximately five to thirty degrees.

14. The method of claim 13 wherein the predetermined angle comprises approximately ten degrees.

15. A method for forming a brushless DC electric motor permanent magnet, the method comprising:
forming a sheet of magnetic material to have first and second ends;
rolling the sheet of magnetic material into a cylinder-shape so that the first and second ends meet at a seam, the cylinder-shape having a rotational axis, the seam skewed relative to the rotational axis.

16. The method of claim 15 wherein the sheet of magnetic material comprises a parallelogram.
